(19) United States
(12) Patent Application Publication
(10) Pub. No.: US 2008/0160773 A1
(43) Pub. Date: Jul. 3, 2008

(54) METHOD OF FABRICATING SEMICONDUCTOR DEVICE

(75) Inventor: Jin Won Lee, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/932,536

(22) Filed: Oct. 31, 2007

(30) Foreign Application Priority Data
Dec. 27, 2006 (KR) 10-2006-0135601

(51) Int. Cl. H01L 21/311

(52) U.S. Cl. 438/703; 257/E21.249

(57) ABSTRACT

A method of fabricating a semiconductor device includes a step of preparing a semiconductor substrate in which an edge region and a cell formation region are defined. Next, an insulating layer is deposited on an entire surface of the semiconductor substrate. The insulating layer deposited on the edge region of the semiconductor substrate is then selectively etched within a chamber of plasma etch equipment equipped with a lower support member, on which the semiconductor substrate can be mounted, and an upper insulating member opposite to the semiconductor substrate. Finally, an annealing process is performed on the insulating layer of the semiconductor substrate.

### CROSS-REFERENCE TO RELATED APPLICATION

This application claims priority to Korean Application No. 10-2006-0135601, filed on Dec. 27, 2006, which is incorporated herein by reference in its entirety.

### BACKGROUND

1. Field of the Invention

The present invention relates to a method of fabricating semiconductor devices, in which reliability of the devices can be improved by etching edge regions of a wafer by using bevel etching.

2. Background of the Invention

During semiconductor fabrication processes, unwanted contaminants can be generated at the edge regions of a semiconductor wafer due to several steps of deposition processes. The contaminants can have a deleterious influence upon the substrate in subsequent processes.

In particular, an unpredictable film quality can be formed at the edge regions of the wafer since equipment and deposition margins may differ with every deposition process performed on the wafer.

FIG. 1 is a plan view of a conventional wafer. FIG. 2 is an enlarged cross-sectional view of a portion “A” of the wafer of FIG. 1.

Referring to FIGS. 1 and 2, a conventional wafer 100 includes a cell formation region C and an edge region E where cells are not actually formed. A variety of transistors, wiring structures, and films are formed in the cell formation region C, forming a plurality of chip dies. In order to form the cell formation region C, the wafer undergoes several deposition processes, etch processes and so on.

For example, an insulating layer 102, an oxide layer 103, a metal layer 104, a nitride layer 105, an oxide layer 106, a metal layer 107 and so forth can be deposited on a semiconductor substrate 101 or etched.

During the deposition processes and the etch processes, deposition or etching may or may not be performed on the edge region of the wafer depending on a deposited material, an etched material, an equipment company, a process condition and/or the like.

Thus, the film quality formed in the edge region E of the wafer 100 may differ from the film quality formed in the cell formation region C in terms of a stack sequence and a film quality characteristic.

FIGS. 3a to 3c are photographs showing the edge regions after an annealing process is performed on the conventional wafer.

FIG. 3a is a scanning electron microscope (SEM) photograph of a wafer edge region, FIG. 3b is a SEM photograph showing the film quality of a 300-μm region far from the wafer edge, and FIG. 3c is a SEM photograph showing the film quality of a 700 μm region far from the wafer edge.

In the film layers formed in the edge region E of the wafer 100, a bubble phenomenon occurs in an annealing process of 400 Celsius degrees or higher in which stress occurs between the film layers and the film layers become inflated.

In the photograph of FIG. 3a, the right side indicates an equipment bottom and two longitudinal bands are shown at points 300 μm and 700 μm from the wafer edge in the edge region E of the wafer 100. The bands are formed by bubble defects 131.

In FIG. 3b, there are shown the bubble defects 131 that look inflated from a lower film quality of the wafer edge region E.

From FIG. 3c, it can be seen that the bubble defects 131, which look inflated from the lower film quality of the wafer edge region E, are pulled out and extend into the cell formation region C.

Thus the film layers inflated by the bubble phenomenon are pulled out during the process. Accordingly, there is a problem in that the film qualities move to the cell formation region C of the wafer, generating circle defects.

FIG. 4 is a graph showing the analysis results of components of the film quality in the edge region E of the conventional wafer.

As shown in FIG. 4, the film quality of the edge region E of the wafer 100 is comprised of a metal component such as cobalt, an insulating component such as sodium or the like as well as silicon.

Cells are not actually formed in the edge region E of the wafer 100. Thus, a state where the silicon substrate is exposed can become the most stable state in the process. However, film layers with unwanted characteristics are formed since several layers are deposited.

FIGS. 5a and 5b show the number of defects occurring in the conventional wafer and a plan view of the wafer, respectively. FIG. 5c shows enlarged images of circle defects formed in the cell formation region of the conventional wafer.

Using equipment for measuring the number of defects occurring in a wafer (e.g., KLA equipment), 30 large particles 132 were found in one conventional wafer, as shown in FIGS. 5a and 5b. Furthermore, as shown in FIG. 5c, in which the large particles 132 are magnified, the circle defects occurred in the edge region of the wafer and then moved to the cell region.

As shown in the magnified view of FIG. 5c, the circle defects are significantly larger than the contact holes 112 of the wafer, resulting in defects in subsequent processes.

Further, if a predetermined number of circle defects occurs in the wafer, there are problems in that the wafer is determined to be defective, the yield is lowered, and the failure rate is increased.

There are also problems in that the defects of the wafer degrade reliability of devices and have a deleterious influence upon subsequent processes.

### SUMMARY OF SOME EXAMPLE EMBODIMENTS

In general, example embodiments of the invention relate to a method of fabricating semiconductor devices, in which bevel etching is performed on the film layers of an edge region of a wafer, significantly reducing the number of circle defects and improving the quality of products.

In accordance with one example embodiment, a method of fabricating a semiconductor device includes a step of preparing a semiconductor substrate in which an edge region and a cell formation region are defined, a step of depositing an insulating layer on an entire surface of the semiconductor substrate, an edge etch process step of selectively etching the insulating layer deposited on the edge region of the semiconductor substrate within a chamber of plasma etch equipment equipped with a lower support member on which the semiconductor substrate can be mounted and an upper insulating member opposite to the semiconductor substrate, and a step of performing an annealing process on the insulating layer of the semiconductor substrate. The edge etch process step is performed on condition that a chamber pressure is within a range from 840 to 1560 mtorr, a distance between the upper insulating member and the semiconductor substrate is within a range from 0.21 to 0.39 mm, RF power is within a range from 490 to 910 W, and a reaction gas includes a mixed gas comprising SF₆, CF₄, and O₂, wherein the flow rate ratio of SF₆, CF₄, and O₂ is 63˜117:63˜117:14˜26 (preferably, 90:90:20).

The edge etch process step can include a stabilization step and an etch step. The stabilization step can be performed for a period of about 10 to 20 seconds on condition that the chamber pressure is within a range from 840 to 1560 mtorr, the distance between the upper insulating member and the semiconductor substrate is within a range from 0.21 to 0.39 mm, the RF power is within a range from 490 to 910 W, and the reaction gas includes a mixed gas comprising SF₆, CF₄, and O₂, wherein the flow rate ratio of SF₆, CF₄, and O₂ is 63˜117:63˜117:14˜26 (preferably, 90:90:20). The etch step is performed for a period of about 20 to 80 seconds (preferably, 40 seconds) on condition that the chamber pressure is within a range from 840 to 1560 mtorr, the distance between the upper insulating member and the semiconductor substrate is within a range from 0.21 to 0.39 mm, the RF power is within a range from 490 to 910 W, and the reaction gas includes a mixed gas comprising SF₆, CF₄, and O₂, wherein the flow rate ratio of SF₆, CF₄, and O₂ is 63˜117:63˜117:14˜26 (preferably, 90:90:20).

At least one of a cobalt layer, a nitride layer, and an oxide layer can be deposited on at least a portion of the semiconductor substrate.

In the edge etch process step, a width etched from an edge of the semiconductor substrate can be in the range of 0.5 to 3 mm.

The etched width can be controlled depending on an etch time.

The etched width can be controlled depending on a size of the upper insulating member.

The method can further include the step of forming a hole in the insulating layer deposited in the cell formation region of the semiconductor substrate before the annealing process is performed on the insulating layer.

In the step of performing the annealing process on the insulating layer, an annealing temperature can range from 400 to 700 Celsius degrees.

In accordance with another embodiment of the present invention, there is provided a method of fabricating a semiconductor device, including a step of depositing a metal layer on a semiconductor substrate in which an edge region and a cell formation region are defined, a step of depositing a nitride layer on the metal layer, a step of depositing an oxide layer on the nitride layer, a step of loading the semiconductor substrate into a chamber of plasma etch equipment, the plasma etch equipment including a lower support member on which the semiconductor substrate can be mounted and a upper insulating member opposite to the semiconductor substrate, a stabilization step that is performed for a period of about 10 to 20 seconds on condition that a chamber pressure is within a range from 840 to 1560 mtorr, a distance between the upper insulating member and the semiconductor substrate is within a range from 0.21 to 0.39 mm, and a reaction gas includes a mixed gas comprising SF₆, CF₄, and O₂, wherein the flow rate ratio of SF₆, CF₄, and O₂ is 63˜117:63˜117:14˜26 (preferably, 90:90:20), an etch step of etching at least one of the metal layer, the nitride layer, and the oxide layer deposited over the semiconductor substrate of the edge region, wherein the etch step is performed for a period of about 20 to 80 seconds on condition that the chamber pressure is within a range from 840 to 1560 mtorr, the distance between the upper insulating member and the semiconductor substrate is within a range from 0.21 to 0.39 mm, the RF power is within a range from 490 to 910 W, and the reaction gas includes a mixed gas comprising SF₆, CF₄, and O₂, wherein the flow rate ratio of SF₆, CF₄, and O₂ is 63˜117:63˜117:14˜26 (preferably, 90:90:20), and a step of unloading the semiconductor substrate from the plasma etch equipment.

The method can further include the steps of, after the step of unloading the semiconductor substrate from the plasma etch equipment, forming a hole in the nitride layer and the oxide layer deposited in the cell formation region of the semiconductor substrate, and performing an annealing process on the semiconductor substrate in a temperature range of 400 to 700 Celsius degrees.

In the etch step, a width etched from an edge of the semiconductor substrate can range from 0.5 to 3 mm region.

The etched width can be controlled depending on an etch time.

The etched width can be controlled depending on a size of the upper insulating member.

### BRIEF DESCRIPTION OF THE DRAWINGS

Aspects of example embodiments of the invention will become apparent from the following description of example embodiments given in conjunction with the accompanying drawings, in which:

FIG. 1 is a plan view of a conventional wafer;

FIG. 2 is an enlarged cross-sectional view of a portion “A” of the wafer of FIG. 1;

FIGS. 3a to 3c are photographs showing edge regions after an annealing process is performed on the conventional wafer;

FIG. 4 is a graph showing the analysis results of components of the film quality of the edge region of the conventional wafer;

FIGS. 5a and 5b show the number of defects occurring in the conventional wafer and a plan view of the wafer, respectively;

FIG. 5c shows enlarged images of circle defects formed in the cell formation region of the conventional wafer;

FIG. 6 is a cross-sectional view of a bevel etching apparatus for etching an edge region of a wafer in accordance with the present invention;

FIG. 7 is a cross-sectional view of an edge region of a wafer in accordance with the present invention from which a material layer of the edge region has been removed by using the bevel etching apparatus of FIG. 6;

FIG. 8 is a flowchart illustrating a method of fabricating a semiconductor device in accordance with the present invention;

FIGS. 9a to 9h are cross-sectional views illustrating the edge region and the cell formation region of the semiconductor device in accordance with the flowchart of FIG. 8;

FIGS. 10a to 10b are photographs showing the edge region after an annealing process is performed on the wafer in accordance with the present invention;

FIG. 11 is a graph showing the analysis results of components of the film quality of the edge region of the wafer in accordance with the present invention;

FIGS. 12a and 12b show a graph showing the number of defects occurring in the wafer and a plan view of the wafer, respectively; and

FIG. 12c shows enlarged images of circle defects formed in the cell formation region of the wafer in accordance with the present invention.

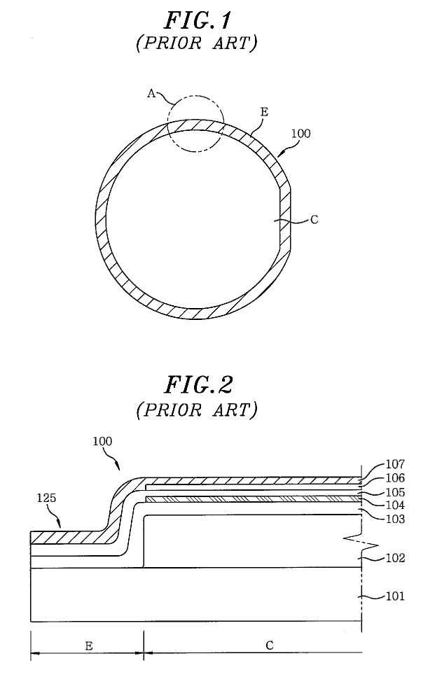

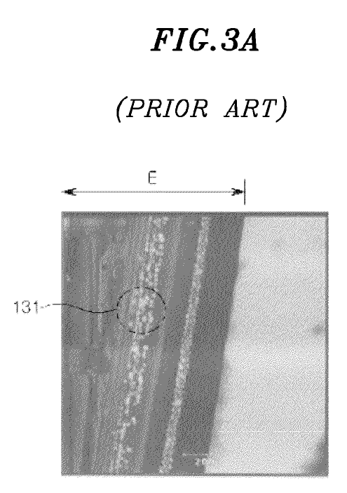

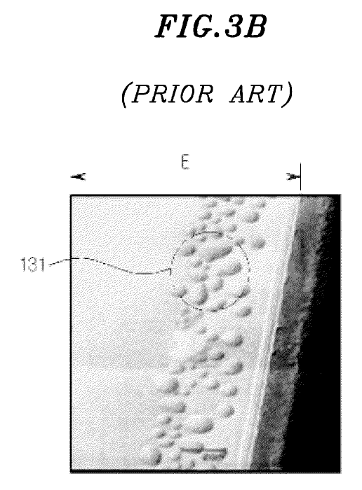

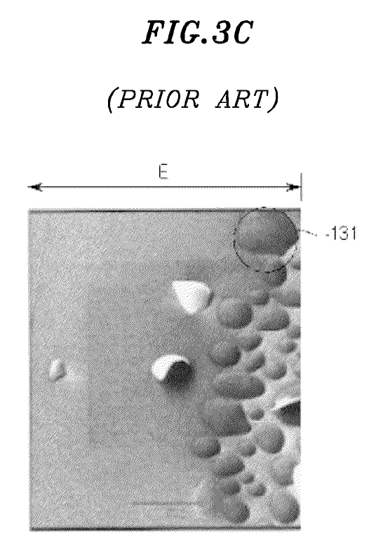

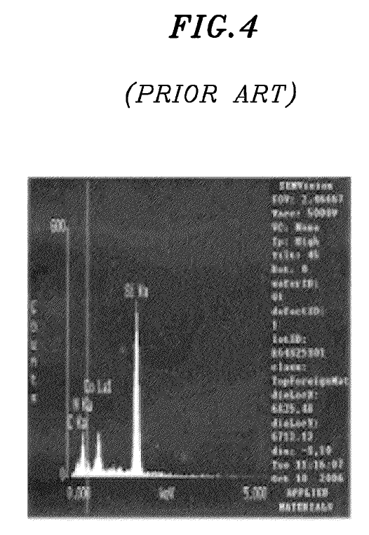

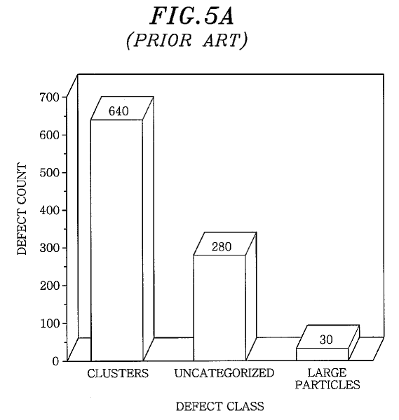

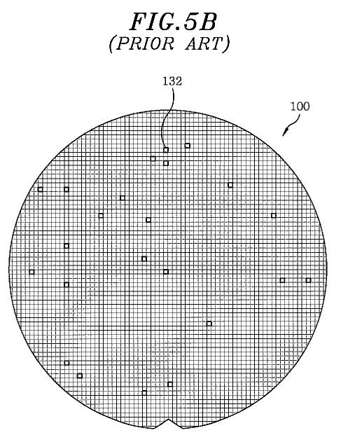

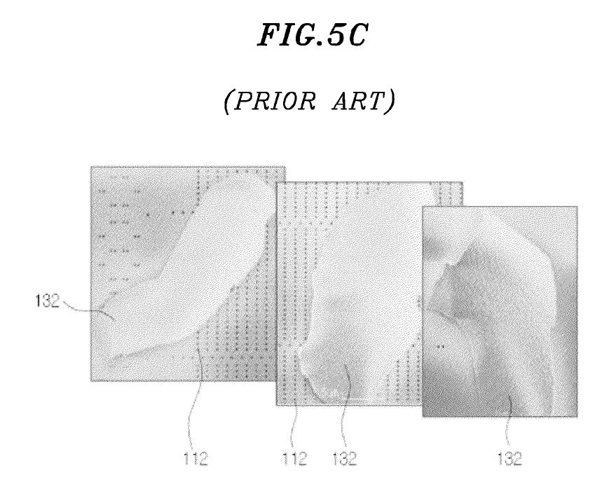

### DETAILED DESCRIPTION OF SOME EXAMPLE EMBODIMENTS

Hereinafter, aspects of example embodiments of the present invention will be described in detail with reference to the accompanying drawings so that they can be readily implemented by those skilled in the art.

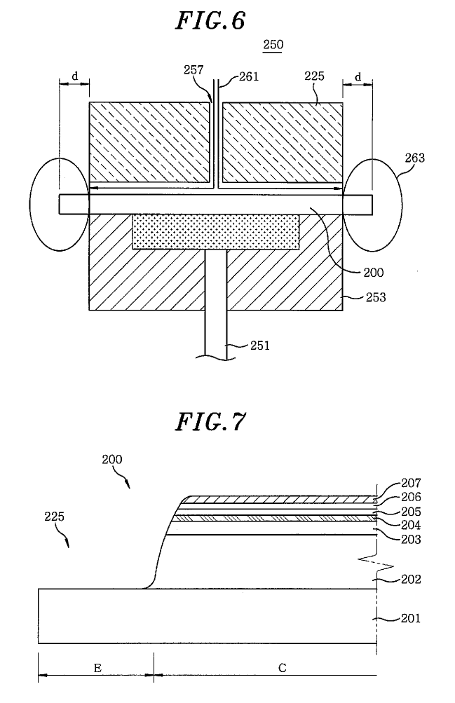

FIG. 6 is a cross-sectional view of a bevel etching apparatus for etching an edge region of a wafer.

Referring to FIG. 6, a bevel etching apparatus 250 may include a bottom chuck 253 mounted on a rear surface of a wafer 200 having a cell formation region C and an edge region E. Bevel etching apparatus 250 may also include an upper insulating member (i.e., a top chuck) 255 having a gas inlet port 257 through which a reaction gas 261 may be injected on the wafer 200 and from which an edge region (a bevel etching region) of the wafer 200 may project. The top chuck 255 may be spaced apart from the top surface of the wafer 100 at a predetermined distance.

The bottom chuck 253 may be rotatably coupled to the rotating shaft 251. A width d of the exposed bevel etching region of the wafer 200 may depend on the size of the top chuck 255. Moreover, the width of the edge region can be identical to that of the bevel etching region or the width d of the bevel etching region can be smaller than that of the edge region. For example, the width d of the bevel etching region can range from 0.5 to 3 mm (preferably, 1 to 2 mm).

Though not shown, bevel etching apparatus 250 may include an upper electrode, to which RF power for generating a plasma 263 is supplied, and a lower electrode disposed in the bottom chuck 253.

Conditions for a bevel etch process employing the bevel etching apparatus 250 may be as follows. The bevel etch process can include a stabilization step and an etch step.

The bevel etch process can further include another stabilization step after the stabilization step and the etch step.

In the bevel etch process, process conditions for the stabilization step can include a chamber pressure that is 1200 mtorr, a distance between the top chuck 255 and the wafer 200 that is 0.3 mm, a reaction gas comprising 90SF6, 90CF4, and 20O2, and a process time of 15 sec.

The stabilization step is a preparation step for bevel etching. In this step, a plasma is not formed because the RF power is not applied.

Process conditions for the etch step can include a chamber pressure that is 1200 mtorr, a distance between the top chuck and the wafer that is 0.3 mm, RF power is 700 W, a reaction gas comprising 90SF₆, 90CF₄, and 20O₂, and a process time that is 30 to 50 sec.

In the etch step, the edge region E of the wafer 200 may be substantially bevel etched.

The process conditions of the stabilization step and the etch step may have an error tolerance of ±30%.

The bevel etch process is described below.

If RF power is applied to the upper electrode and the lower electrode under conditions described above while the reaction gas 261, mixed under conditions described above, flows through the gas inlet port, the plasma 263 is formed within the bevel etching apparatus 250.

In this case, only the edge region of the wafer 200 projects from the top chuck 255. Thus, the generated plasma reacts with patterns of the edge region of the wafer 200, so that etching is performed during a process time. The width d that is etched from the edge of the semiconductor substrate can range from 0.5 to 3 mm.

The etched width d can be controlled by an etch time.

In addition, or alternatively, the etched width d can be controlled in the range of 0.5 to 3 mm by controlling the plasma depending on the size of the upper insulating member (i.e., top chuck) 255.

In the wafer 200 fabricated according to the foregoing processes, not only circle defects can be eliminated, but also defects that may occur at the edge region and the backside of the wafer, can be removed effectively. Accordingly, the product quality can be improved and reliability of devices and processes can be enhanced.

FIG. 7 is a cross-sectional view of the edge region of the wafer from which the material layer of the edge region has been removed by using the bevel etching apparatus 250 of FIG. 6.

Referring to FIG. 7, the wafer 200 may include the cell formation region C and the edge region E in which cells are not actually formed.

A variety of transistors, wiring structures and films may be formed in the cell formation region C to form a plurality of chip dies.

In order to form the cell formation region C, the wafer 200 may undergo several deposition and etch processes, etc.

For example, an insulating layer 202, an oxide layer 203, a metal layer 204, a nitride layer 205, an oxide layer 206, a metal layer 207 and so forth may be deposited over or etched from a semiconductor substrate 201.

In the deposition and etch processes, unwanted substances may be formed on the edge region E of the wafer 200 depending on a deposited material, an etched material, equipment companies, and/or process conditions. All or a portion of a material layer 225 may be etched and removed from the edge region E of the wafer 200, so that the semiconductor substrate 201 is exposed. For example, the material layer 225 of the edge region E of the wafer 200 can be removed by the bevel etch process described with reference to FIG. 6.

In the wafer fabricated according to the present invention, not only circle defects can be eliminated, but also defects, which may occur at the edge region and the backside of the wafer, can be removed effectively. It is therefore possible to improve the product quality and reliability of devices and processes.

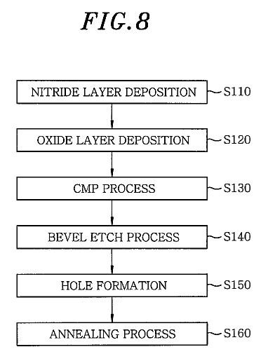

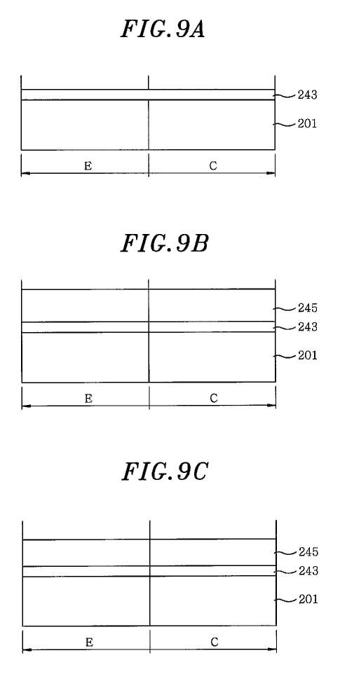

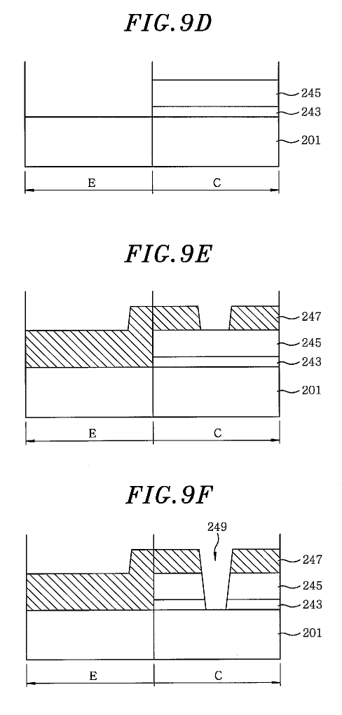

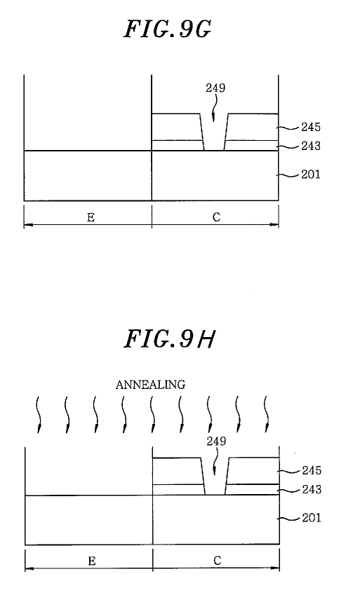

FIG. 8 is a flowchart illustrating an exemplary method of fabricating the semiconductor device. FIGS. 9a to 9h are cross-sectional views illustrating the edge region and the cell formation region of the semiconductor device according to the flowchart of FIG. 8.

The process of forming the interlayer insulating layer, of numerous processes of a semiconductor fabrication process, has been described once as an example. Thus, the following process can be repeated several times.

In the semiconductor substrate are defined the edge region E and the cell formation region C.

Referring to step S110 of FIG. 8 and FIG. 9a, a nitride layer 243 may be formed on the semiconductor substrate 201 on which an underlying structure is formed.

The nitride layer 243 may be deposited both on the edge region E and the cell formation region C. Alternatively, a metal layer can be deposited on the semiconductor substrate 201 before the nitride layer 243 is deposited. For example, the metal layer can be formed from a cobalt (Co) layer, a titanium (Ti) layer or a titanium nitride (TiN) layer. The metal layer can have a single layer or a multi-layer.

Referring to step S120 of FIG. 8 and FIG. 9b, an oxide layer 245 may be deposited on the nitride layer 243. The oxide layer 245 can include at least one of tetra-ethyl-ortho-silicate (TEOS), fluorinated silica glass (FSG), and undoped silicate glass (USG). The oxide layer 245 can have a top surface curved by the underlying structure formed on the semiconductor substrate 201.

The oxide layer 245 may be deposited both on the edge region E and the cell formation region C.

Referring to step S130 of FIG. 8 and FIG. 9c, the oxide layer 245 may be polished by a chemical mechanical polishing (CMP) process.

Referring to step S140 of FIG. 8 and FIG. 9d, the material layers of the oxide layer 245 and the nitride layer 243 formed in the edge region E may be removed by the bevel etch process described above, thus exposing the semiconductor substrate 201.

Conditions for the bevel etch process and the bevel etching apparatus may be the same as those described above with reference to FIG. 6.

In step S150, a contact hole 249 may be formed in the cell formation region C, which is shown in FIGS. 9e to 9g.

Referring to FIG. 9e, a photoresist pattern 247 may be formed on the oxide layer 245 except for a region where the contact hole 249 will be formed.

Referring to FIG. 9f, the oxide layer 245 and the nitride layer 243 may be etched by using the photoresist pattern 247 as an etch mask, thus forming the contact hole 249 in the oxide layer 245 and the nitride layer 243.

The semiconductor substrate 201 can be exposed through the contact hole 249, and an underlying structure formed on the semiconductor substrate 201, such as a metal wiring, can be exposed.

Referring to FIG. 9g, the photoresist pattern 247 used as the etch mask may be removed.

Referring to step S160 and FIG. 9h, an annealing process may be performed on the oxide layer 245 and the nitride layer 243 having the contact hole 249 formed therein in order to improve a film quality characteristic.

The annealing process can be performed in a temperature range of 400 to 700 Celsius degrees (preferably, 450 Celsius degrees).

Because the material layers are not formed in the edge region E of the wafer 200, having been etched away, defects are not generated in the edge region E despite the annealing process being carried out at a high temperature.

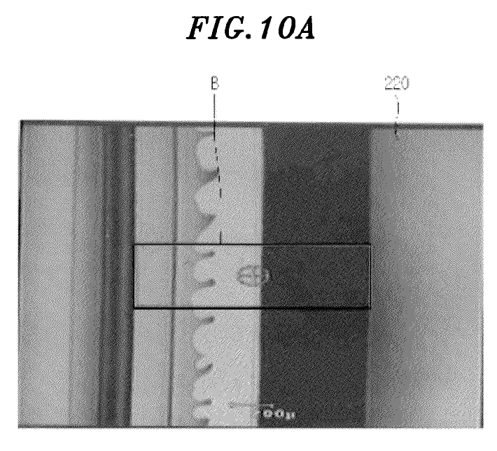

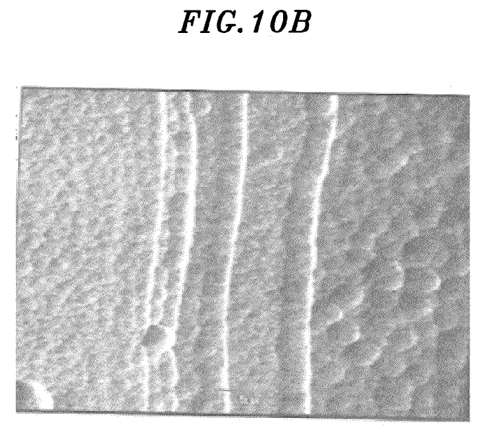

FIGS. 10a to 10b are photographs showing the edge region after an annealing process is performed on the wafer.

FIG. 10a is a SEM photograph of the wafer edge region E, and FIG. 10b is an enlarged view of a region “B” of FIG. 10a.

From FIGS. 10a and 10b, it can be seen that the edge region E of the wafer 200 does not have a bubble phenomenon and is clean since the silicon substrate is exposed.

An equipment bottom 220 is shown on the right side of FIG. 10a. It can also be seen that a bubble phenomenon does not occur in the wafer edge region E on the left side of FIG. 10a.

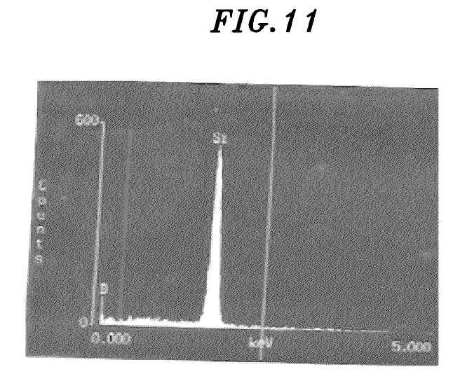

FIG. 11 is a graph showing the analysis results of components of the film quality of the edge region of the wafer.

As shown in FIG. 11, in the edge region E of the wafer 200, only silicon (Si) is detected as a main peak as a result of the component analysis because the semiconductor substrate is exposed.

Therefore, since the material layers are not formed in the edge region E of the wafer 200, defects are not generated by the annealing process and do not become sources of defects in the wafer.

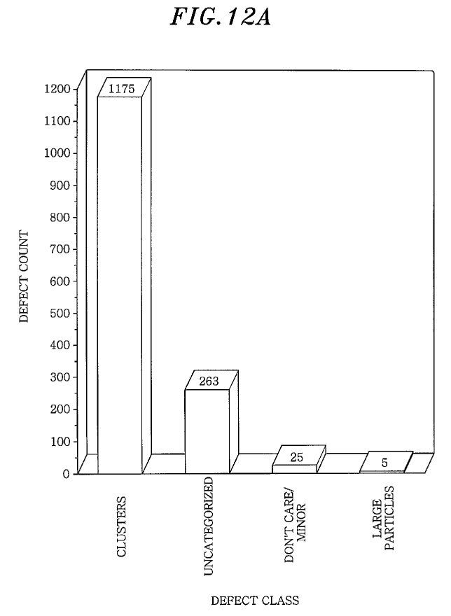

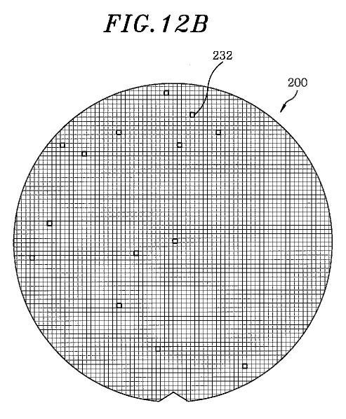

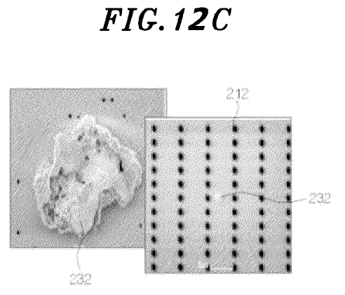

FIGS. 12a and 12b show a graph showing the number of defects occurring in the wafer and a plan view of the wafer, respectively. FIG. 12c shows enlarged images of circle defects formed in the cell formation region of the wafer in accordance with the present invention.

Referring to FIG. 12a, as a result of measuring defects of a wafer fabricated according to the methods described above (by employing, for example, KLA equipment), five or less large particles 232 were found. From FIG. 12c, it can be seen that circle defects are completely removed and the size of defects is smaller than that of contact holes 212 of the wafer 200.

Accordingly, in the wafer fabricated according to embodiments of the present invention, not only circle defects can be eliminated, but also defects that may occur at the edge region and the backside of the wafer can be removed effectively. Accordingly, the product quality can be improved and reliability of devices and processes can be enhanced.

As described above bevel etching is used in semiconductor devices. Thus, not only circle defects can be eliminated, but also defects that may occur at the edge region and the backside of the wafer can be removed effectively. Accordingly, there are advantages in that the product quality can be improved and reliability of devices and processes can be enhanced.

Further, there is an advantage in that defects can be reduced significantly in the semiconductor device fabrication process and the yield can be improved.

While the invention has been shown and described with respect to the specific embodiments, it will be understood by those skilled in the art that various changes and modifications may be made without departing from the spirit and scope of the invention as defined in the following claims.

What is claimed is:

1. A method of fabricating a semiconductor device, comprising:
a step of preparing a semiconductor substrate in which an edge region and a cell formation region are defined;
a step of depositing an insulating layer on an entire surface of the semiconductor substrate;
an edge etch process step of selectively etching the insulating layer deposited on the edge region of the semiconductor substrate within a chamber of plasma etch equipment equipped with a lower support member on which the semiconductor substrate can be mounted and an upper insulating member opposite to the semiconductor substrate; and
a step of performing an annealing process on the insulating layer of the semiconductor substrate.

2. The method of claim 1, wherein:
the edge etch process step is performed on condition that a chamber pressure is 840 to 1560 mtorr, a distance between the upper insulating member and the semiconductor substrate is 0.21 to 0.39 mm, RF power is 490 to 910 W, and a reaction gas includes a mixed gas comprising SF₆, CF₄, and O₂, wherein the flow rate ratio of SF₆:CF₄:O₂ is 63˜117:63˜117:14˜26.

3. The method of claim 2, wherein:
the edge etch process step comprises a stabilization step and an etch step,
the stabilization step is performed for a period of about 10 to 20 seconds on condition that the chamber pressure is 840 to 1560 mtorr, the distance between the upper insulating member and the semiconductor substrate is 0.21 to 0.39 mm, and the reaction gas includes a mixed gas comprising SF₆, CF₄, and O₂, wherein the flow rate ratio of SF₆:CF₄:O₂ is 63˜117:63˜117:14˜26, and the etch step is performed for a period of about 20 to 80 seconds on condition that the chamber pressure is 1200 mtorr, the distance between the upper insulating member and the semiconductor substrate is 0.21 to 0.39 mm, the RF power is 490 to 910 W, and the reaction gas includes a mixed gas comprising SF₆, CF₄, and O₂, wherein the flow rate ratio of SF₆:CF₄:O₂ is 63˜117:63˜117:14˜26.

4. The method of claim 1, wherein at least one of a cobalt layer, a nitride layer, and an oxide layer is deposited on at least a portion of the semiconductor substrate.

5. The method of claim 1, wherein in the edge etch process step, a width etched from an edge of the semiconductor substrate is in the range of 0.5 to 3 mm.

6. The method of claim 5, wherein the etched width is controlled depending on an etch time.

7. The method of claim 5, wherein the etched width is controlled depending on a size of the upper insulating member.

8. The method of claim 1, further comprising the step of forming a hole in the insulating layer deposited in the cell formation region of the semiconductor substrate before the annealing process is performed on the insulating layer.

9. The method of claim 1, wherein in the step of performing the annealing process on the insulating layer, an annealing temperature is within a range of 400 to 700 Celsius degrees.

10. A method of fabricating a semiconductor device, comprising:
a step of depositing a metal layer on a semiconductor substrate in which an edge region and a cell formation region are defined;
a step of depositing a nitride layer on the metal layer;
a step of depositing an oxide layer on the nitride layer;
a step of loading the semiconductor substrate into a chamber of plasma etch equipment, the plasma etch equipment including a lower support member on which the semiconductor substrate can be mounted and a upper insulating member opposite to the semiconductor substrate;
a stabilization step that is performed under a specific chamber pressure by using a reaction gas;
an etch step of etching at least one of the metal layer, the nitride layer, and the oxide layer deposited over the edge region of the semiconductor substrate; and
a step of unloading the semiconductor substrate from the plasma etch equipment.

11. The method of claim 10, wherein:
the stabilization step is performed for a period of about 10 to 20 seconds on condition that a chamber pressure is 840 to 1560 mtorr, a distance between the upper insulating member and the semiconductor substrate is 0.21 to 0.39 mm and a reaction gas includes a mixed gas comprising SF₆, CF₄, and O₂, wherein the flow rate ratio of SF₆:CF₄:O₂ is 63˜117:63˜117:14˜26; and
wherein the etch step is performed for a period of about 20 to 80 seconds on condition that the chamber pressure is 840 to 1560 mtorr, the distance between the upper insulating member and the semiconductor substrate is 0.21 to 0.39 mm, the RF power is 490 to 910 W, and the reaction gas includes a mixed gas comprising SF₆, CF₄, and O₂, wherein the flow rate ratio of SF₆:CF₄:O₂ is 63˜117:63˜117:14˜26.

12. The method of claim 10, further comprising the steps of:
after the step of unloading the semiconductor substrate from the plasma etch equipment,
forming a hole in the nitride layer and the oxide layer deposited in the cell formation region of the semiconductor substrate; and
performing an annealing process on the semiconductor substrate in a temperature range of 400 to 700 Celsius degrees.

13. The method of claim 10, wherein in the etch step, a width etched from an edge of the semiconductor substrate is in the range of 0.5 to 3 mm region.

14. The method of claim 13, wherein the etched width is controlled depending on an etch time.

15. The method of claim 13, wherein the etched width is controlled depending on a size of the upper insulating member.
